(19) United States
(12) Patent Application Publication
(10) Pub. No.: US 2013/0241530 A1
(43) Pub. Date: Sep. 19, 2013

(54) Measuring Device for Determining and/or Monitoring at Least One Process Variable

(71) Applicants: Armin Wernet, Rheinfelden (DE); Kaj Uppenkamp, Wehr (DE); Franco Ferraro, Schworstadt (DE); Wolfgang Brutschin, Schopfheim (DE)

(72) Inventors: Armin Wernet, Rheinfelden (DE); Kaj Uppenkamp, Wehr (DE); Franco Ferraro, Schworstadt (DE); Wolfgang Brutschin, Schopfheim (DE)

(73) Assignee: Endress + Hauser GmbH + Co. KG, Maulburg (DE)

(21) Appl. No.: 13/885,757

(22) PCT Filed: Nov. 15, 2011
(86) PCT No.: PCT/EP2011/070100

§ 371 Date: May 16, 2013

(30) Foreign Application Priority Data
Nov. 19, 2010 (DE) 102010044180.5

(51) Int. Cl. G01R 31/28

(52) U.S. Cl. CPC G01R 31/28
USPC 324/76.11

(57) ABSTRACT

A measuring device for determining and/or monitoring at least one process variable, comprising: a sensor unit; a first electronics unit which has a first microcontroller, and a second electronics unit which has a second microcontroller, and which is connected with the first electronics unit via a galvanically isolated transmission unit for energy- and data transmission. The first microcontroller produces at least one signal, which can vary in at least one characteristic, and supplies the signal to the transmission unit, that the signal controls the energy- and data transmission, that the first microcontroller and/or the second microcontroller determines at least one current operating parameter, and that the first microcontroller sets at least one characteristic of the signal as a function of the operating parameter.

The present invention relates to a measuring device for determining and/or monitoring at least one process variable with a sensor unit having at least one sensor sensitive for the process variable. The process variable is, for example, fill level, density, viscosity, temperature, pressure, or pH-value of a medium.

A multitude of varied measuring devices are known for determining and/or monitoring process variables in process- and automation technology. An example of a fill-level measuring device is that manufactured and sold by the assignee under the mark, “Liquiphant”. The “Liquiphant” device uses a vibronic measuring principle and its sensor unit has an oscillatory fork, which can be excited to execute mechanical oscillations. For use in explosion-endangered regions, such measuring devices often have a galvanic isolation, by which, for example, the medium-contacting sensor part located in the explosion-endangered region is isolated from energy supply, user interface, etc. Across the galvanic isolation, there occurs, most often, not only energy supply of the sensor unit, but also communication with the sensor unit. As a rule, the measuring device includes, for this, two electronic units, between which a galvanically isolated interface is present. This is implemented, for example, by at least one capacitor or transformer.

A form of energy- and data transmission via an interface equipped with a transformer is described in DE 10 2006 051 900 A1. In such case, data transmission from the first electronics unit to the second electronics unit occurs via modulation of the frequency and/or amplitude of the energy transmission, while data from the second to the first electronics unit are transmitted by means of modulation of the electrical current requirement of the second electronics unit. Both electronic units contain a processor. Activation of the transformer occurs via analog components, which set the parameters of the signal transmission, such as, for example, pulse- or pause duration. The fixed parameters bring the disadvantage that the efficiency of energy transmission is maximum only under certain conditions. Modification of the hardware circuit, which would enable influencing the efficiency by changing the parameters, would be associated with impractical circuit complexity.

A further disadvantage comes about in the case of start-up of the measuring device. During start-up, certain specifications must be adhered to. Thus, 4-20 mA devices, for example, must not assume values, which lie within this region associated with measured values, in order to prevent the triggering of corresponding reactions of following devices. Since analog components make use of no control function and, consequently, can not detect an exceeding of predetermined limits, it is usual to perform the start-up of the device with an electrical current lying clearly below or above the measured value range, e.g. <3.6 mA. Start-up requires then correspondingly more time. A measuring device should, however, be operational as rapidly as possible.

An object of the invention is to provide a measuring device of the above described type, whose energy- and/or data transmission is matched to existing requirements. Furthermore, a method for operating such a measuring device is to be provided, which enable a matching of the energy- and/or data transmission to the existing requirements.

The object as regards the measuring device is achieved by features including that the first microcontroller produces at least one signal, which can vary in at least one characteristic, and supplies the signal to the transmission unit, that the signal controls energy- and data transmission, that the first microcontroller and/or the second microcontroller determines at least one current operating parameter, and that the first microcontroller sets at least one characteristic of the signal as a function of the operating parameter.

The first and/or the second microcontroller determines preferably the current operating state or the current efficiency of the energy transmission as operating parameter. Different operating states are, for example, start-up, measurement operation, and standby or energy saving mode. The settable characteristics of the signal are, for example, frequency, pulse duration, pause duration or the pulse duration to pause duration ratio.

For a long time now, processors possibly present in the electronics unit have delivered only a binary control signal for control of downstream components, which then produce the actual signals for energy- and/or data transmission. According to the invention, the primary side microcontroller now directly produces the control signal for energy- and/or data transmission. In this way, a high flexibility in the form of the signal is enabled. By way of the variable frequency or the variable pulse to pause ratio, the signal is adaptable as regards present, existing requirements, such as e.g. the energy requirement. The first microcontroller adapts the signal dynamically to the present requirements, respectively enables, furthermore, an adapting of the signal to changing environmental conditions, such as, for example, temperature. The characteristics of the signal are not fixedly preset, but, instead, are regularly controlled.

In a first embodiment of the solution of the invention, the first microcontroller adapts at least one characteristic of the signal in such a manner to a current operating state of the measuring device and/or sets the characteristic in such a manner that the efficiency of the energy transmission is optimized. Especially, in the case of continuous monitoring of efficiency, options include a control of the efficiency by optimally adapting the characteristics and/or the making of a statement concerning the state of the measuring device with an eye toward predictive maintenance. Instead of efficiency, for example, the output voltage can be optimized.

In an embodiment, the characteristic of the signal set by the first microcontroller is the frequency of the signal and/or the pulse duration to pause duration ratio. For example, at least one of the microcontrollers determines the present efficiency as operating parameter and the first microcontroller adapts the pulse duration to pause duration ratio of the signal for optimizing the efficiency.

In the case of a further development of the invention, the transmission unit includes at least one transformer. In such case, it can be a forward converter or a flyback converter.

In an embodiment of the measuring device of the invention, the transmission unit is a push pull converter, preferably a push pull flux converter. Two control signals are required for push pull activation, so that the first microcontroller correspondingly produces a first and a second signal, wherein the second signal is essentially an inverted first signal.

An advantageous embodiment of the measuring device provides that the first microcontroller registers a present input power of the transmission unit, that the second microcontroller registers a present output power of the transmission unit, and that the ‘first microcontroller and/or the second microcontroller ascertains from the registered input power and the registered output power the present efficiency of the energy transmission. Preferably, the first microcontroller ascertains the efficiency. Based on the efficiency, the optimal working point of the energy- and data transmission is ascertainable. By the variability of the signal for controlling the energy- and data transmission, the characteristics of the signal are controllable in such a manner that the transmission, at any time, occurs at the optimal working point. This makes the measuring device very energy efficient.

In an especially advantageous form of embodiment, the measuring device evaluates the efficiency for diagnostic purposes, especially as regards predictive maintenance. By continuously monitoring efficiency, a prognosis can be made as to when a declining efficiency will be under a value required for undisturbed operation of the measuring device and, thus, maintenance or a replacement of the measuring device will be necessary. A worsening of the efficiency can be caused by aging of the components of the electronic units, as well as by environmental conditions, such as e.g. high moisture content or high temperatures. In an embodiment, the measuring device further includes a temperature sensor for monitoring temperature. The information concerning temperature can likewise be used for diagnosis.

In a therewith connected embodiment, the first microcontroller and/or the second microcontroller determines from the ascertained efficiency whether a coil break is present in the transformer and produces in the case of a coil break a corresponding defect report. The measuring device is able, by evaluating the ascertained efficiency, to monitor itself for coil breaks.

An embodiment of the invention provides that the first microcontroller has different operating modes, which are characterized by certain values of at least one characteristic of the signal, that an operating mode is associated with each operating state of the measuring device, and that the microcontroller sets the operating mode as a function of the current operating state. For an operating mode, at least one set of starting values for the characteristics is defined. As time goes on, the first microcontroller adapts the characteristics, as required, to the present requirements. If, for example, the energy requirement of the sensor unit is smaller than expected, so that a smaller energy transmission is sufficient, the first microcontroller lessens the pulse duration, or the pulse duration to pause duration ratio, of the signal, in order to control the energy transmission. If the need arises, the first microcontroller brings the ratio back up.

In a further development, the first microcontroller registers an identification, or ID, of the sensor unit, and sets, as a function of the sensor unit present, the at least one characteristic of the signal in such a manner that the energy transmission is matched to the energy requirement of the respective sensor unit. Additionally, the characteristics are dynamically controllable.

The object of the invention is achieved furthermore by a method for operating a measuring device having the above features. The solution includes features that at least one signal having at least one variable characteristic is produced and fed to the transmission unit, that energy- and data transmission are controlled by the signal, that at least one current operating parameter is determined, and that at least one characteristic of the signal is set as a function of the operating parameter.

The terminology, characteristics, means variables characteristic for the signal, such as frequency and pulse duration to pause duration ratio. In a preferred embodiment of the transmission unit, such comprises a push pull converter. Preferably, for control, consequently, a first signal and a second signal are produced, wherein the second signal is essentially an inverted first signal. In an embodiment of the method, the at least one signal is matched to the operating conditions, i.e., for example, the sensor-side energy consumption is ascertained and the energy transmission correspondingly controlled. Thus, the efficiency of the energy transmission is optimized. In a variant, the first electronics unit recognizes the sensor type that is present, and the characteristics are set corresponding to the typical requirements of such sensor type, such as e.g. energy requirement. As time goes on, the characteristics are dynamically adapted to current requirements. The sensor recognition occurs, in such case, typically via communication with the microcontroller of the secondary side or via a correspondingly set port. In an embodiment, the operating state is ascertained and the signal correspondingly produced. For example, a start routine is defined, with which the system can be safely transferred from the turned-off state or from the resting state into the active, measuring state.

The invention will now be explained in greater detail based on the appended drawing for measuring device and method together. The figures of the drawing show as follows:

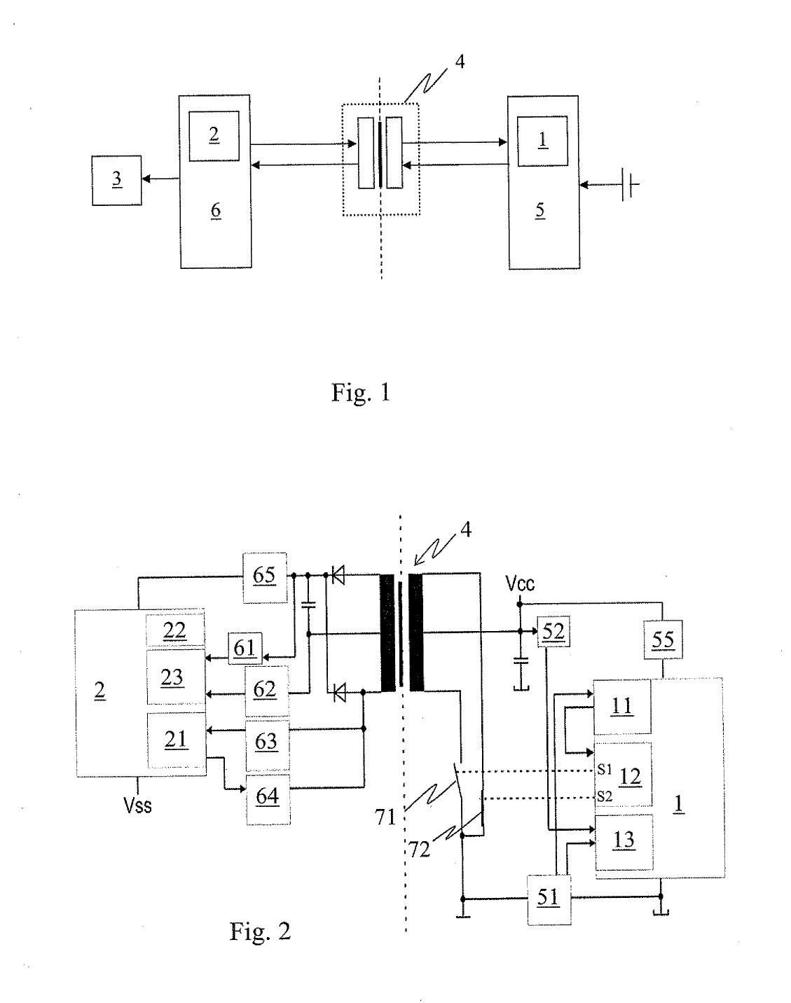

FIG. 1 a schematic representation of the components of a measuring device of the invention;

FIG. 2 a block diagram of the electronic components.

FIG. 1 shows the essential components of a measuring device of the invention. Sensor 3 and the second electronics unit 6 form the sensor unit. Sensor 3 is, for example, an oscillatable unit, especially an oscillatory fork, which is excited by a drive unit to execute mechanical oscillations. This is connected with the first electronics unit 5 via a galvanically isolated interface in the form of transmission unit 4. The first electronics unit 5 supplies energy to the sensor unit, so that the side of the galvanic isolation associated with the sensor 3 can be referred to as the secondary side and the side associated with the first electronics unit 5 as the primary side. Besides the energy source, there can be located on the primary side other components such as e.g. display elements and interfaces to interaction elements or servicing elements.

FIG. 2 discloses a schematic block diagram of the first electronics unit 5, the second electronics unit 6 and transmission unit 4. The first electronics unit 5 includes a first microcontroller 1, which has a digital interface 11, a timer 12 and an analog/digital converter 13. The first microcontroller 1 obtains the energy required by it via a voltage regulator 55 from the voltage source Vcc, which provides the supply voltage for transmission unit 4. Transmission unit 4 is preferably a push pull converter, especially a push pull flux converter, having a transformer with center tapping. On the primary side, the transformer middle tap is connected with the supply voltage Vcc. The respective other ends are connectable with ground via a controllable switch 71, 72.

Operation of the push pull converter occurs digitally by means of the first microcontroller 1. The digital interface 11 controls the input of the timer 12. For example, the digital interface 11 is a UART. In an alternative embodiment, the timer 12 is operated internally, i.e. by a signal within the first microcontroller 1. Timer 12 has two outputs, on which a first signal S1 and a second signal S2 are output. During applied low-level, timer 12 produces the first signal S1 with a frequency f1; during high-level a frequency f2. In other words, the timer 12 produces a frequency modulated signal S1, wherein the frequency f1 corresponds to a logical zero and the frequency f2 a logical one. The first signal S1 controls the first switch 71. The second signal S2 controls the second switch 72 and corresponds essentially to an inverted first signal S1. The edges of the pulses of the second signal S2 are, however, opposite those of the first signal S1 in such a manner, offset by a pause time tp, that at no time are the two signals S1, S2 simultaneously at high-level, since this would cause a short circuit. Switches 71, 72 can be implemented, for example, in the form of transistors.

The different frequencies f1 and f2 serve for communication from the primary side to the secondary side. For transmission of a logical 0, the timer 12 produces signals with the frequency f1; for transmission of a logical 1, the frequency f2. At the same time, also energy transmission is controlled with the signals S1 and S2. The longer the pulse duration of the signals S1, S2, the greater is the amount of energy fed, wherein the transmission of this energy has limits set by saturation of the transformer core. Outside of the communication phases, for example, the signal S1, S2 with logical 1 has the frequency f2. The pulse duration of the signal S1, S2 with the frequency f2 determines, consequently, the transferred energy. According to the invention, the energy transmission is matched to the current energy requirement. For this, the second microcontroller 2 determines on the secondary side the current energy requirement and informs the first microcontroller 1 thereof, whereupon this sets the pulse duration to pause duration ratio correspondingly. The frequencies f1, f2 are factors of the system clock of the first microcontroller 1 and can be adjusted as much as desired. Since the second signal S2 essentially equals the inverted first signal S1, this means that, in the case of a change of the characteristics, the characteristics of the first signal S1 and the characteristics of the second signal S2 are equally changed.

Same as in the case of the first electronics unit 5, the second electronics unit 6 includes a second microcontroller 2, which has a timer 22, a digital interface 21 and an analog/digital converter 23. The energy supply of the second microcontroller 2 comes from the voltage controller 65 of the transmission unit 4.

Voltage controller 65 controls the transferred voltage to that required for the input voltage of the second microcontroller 2. The ground potential of the second microcontroller 2 is labeled here with Vss.

For decoding the transmitted information, the secondary side second electronics unit 6 includes a demodulator 63. This converts the frequency modulated signal back into a binary signal. For example, the demodulator 63 is a lowpass or bandpass filter, whose limit frequency, respectively limit frequencies, is, respectively are, set corresponding to the frequencies f1 and f2.

The second electronics unit 6 includes a current converter 61 and a level converter 62. The current converter 61 contains a resistor for changing the applied voltage into a corresponding electrical current and leads this to the analog/digital converter 23. The level converter 62 receives the transferred voltage and forwards it to the analog/digital converter 23, wherein the voltage is adjusted to the digitizable region of the analog/digital converter 23, respectively the supply voltage of the second microcontroller 2. From the present values of electrical current and voltage, the second microcontroller 2 determines the present power.

For communication with the primary side, the secondary side uses a pulse-like electrical current modulation. For this, the electrical current modulator 64 connected with the signal output of the digital interface 21 increases the electrical current requirement of the secondary side during the presence a logical one. In an advantageous embodiment, the electrical current requirement is increased not uniformly for the entire pulse duration of the signal output by the digital interface 21, but, instead, there are produced during the pulse duration a number of short electrical current pulses, so that the additional electrical current consumption is kept small.

In order to decode the electrical current modulation and, thus, the information transmitted from the secondary side, the first electronics unit 5 includes a current converter 51 on the primary side. This is connected after the two switches 71, 72 and connected with the ground of the first microcontroller 1. Current converter 51 contains at least one resistor of known value, via which the electrical current is converted into a corresponding voltage. For ascertaining the electrical current consumption, the current converter 51 supplies this voltage to the analog/digital converter 13. Additionally, the current converter 51 contains a demodulator, which prepares the communication signal for the digital interface 11, to which it then supplies the prepared signal.

The ascertained electrical current value serves, besides for ascertaining the information content transmitted by the electrical current modulation, for determining the present primary side power. For this, additionally knowledge of the currently applied voltage is necessary. The information concerning the currently applied voltage is provided to the first microcontroller 1 from the level converter 52. This adapts the voltage to the digitizable region of the analog/digital converter 13 and forwards such thereto. In the case of known division ratio, the microcontroller 1, thus, knows the actual voltage, so that it can then ascertain the power.

Preferably, the second microcontroller 2 transmits to the first microcontroller 1 the power measured on the secondary side. The first microcontroller 1 determines then the present efficiency of the transmission. If the efficiency is not optimal, the first microcontroller 1 controls, for example, the characteristics of the signals S1, S2 in such a manner that the efficiency increases. If the efficiency, in spite of readjustment of the characteristics, increases not as expected, probably a coil break is present and the microcontroller 1 produces a defect report. In an embodiment, the microcontroller 1 first operates the two coils separately and determines the efficiency for each case. In another embodiment, the first microcontroller 1 increases the supplied energy, when the secondary side reports a decrease of power or transmitted energy. If the power, respectively transmitted energy, does not increase, the first microcontroller 1 produces an error report. The error report is effected, for example, by turning-on an LED on the device or issued in the form of a request for maintenance via a bus system.

Preferably, different operating modes are implemented in the first microcontroller 1, which are distinguished by a set of certain characteristics. Associated with each operating state is then an operating mode. The operating state is automatically recognized and the corresponding operating mode set, i.e. the signals S1, S2 are produced with the corresponding frequencies f1, f2 and corresponding pulse duration to pause duration ratio.

An operating state is, for example, the bringing of the measuring device up in the case of start-up or from standby. Preferably, a startup routine with dynamic electrical current control is specified. The electrical current consumption of 4-20 mA devices must lie during start-up outside of the 4-20 mA range. According to the invention, there is implemented with the current converter 51 a control function in the first electronics unit 5, with which the current electrical current consumption is registerable. Preferably, consequently, an electrical current lying only scarcely below the impermissible region is used and, in given cases, controlled down, in case the electrical current consumption rises. This accelerates the startup procedure and increases, thus, the availability of the measuring device.

A further operating state is that of measurement operation. Predominantly, during measurement operation, energy is transmitted from the primary side to the secondary side, wherein the signal corresponding to logical one lies on the transmission unit. The corresponding frequency and the pulse duration to pause duration ratio are matched to the energy requirement of the sensor unit, respectively the secondary side. Preferably, the primary side possesses a function for automatic sensor type recognition and selects the characteristics corresponding to the sensor-specific energy consumption. Advantageously, the first microcontroller 1 has for each sensor unit connectable with the primary side an operating mode associated with measurement operation of this sensor unit, wherein one operating mode can also be associated with a plurality of sensor units. Of course, there occurs also here, in case required, a dynamic adapting of the characteristics during measurement operation, e.g. in the case of an increased electrical current requirement or for optimizing efficiency.

List of Reference Characters

1 first microcontroller

11 digital interface

12 timer

13 analog/digital converter

2 second microcontroller

21 digital interface

22 timer

23 analog/digital converter

3 sensor

4 transmission unit

5 first electronics unit

51 current converter

52 level converter

55 voltage controller

6 second electronics unit

61 current converter

62 level converter

63 demodulator

64 electrical current modulator

65 voltage controller

71 switch

72 switch

S1 first) signal

S2 second signal

Vss reference potential of the second microcontroller

Vcc direct voltage source

1-10. (canceled)

11. A measuring device for determining and/or monitoring at least one process variable, comprising:
a sensor unit having at least one sensor sensitive for the process variable;
a first electronics unit, which is associated with an energy supply unit and which has a first microcontroller; and
a second electronics unit, which is associated with said sensor unit and has a second microcontroller, and which is connected with said first electronics unit via a galvanically isolated transmission unit for energy- and data transmission, wherein:
first microcontroller produces at least one signal, which can vary in at least one characteristic, and supplies the signal to said transmission unit, said at least one signal controls energy- and data transmission; and
said the first microcontroller and/or said second microcontroller determines at least one current operating parameter, and
the first microcontroller sets at least one characteristic of the signal as a function of the operating parameter.

12. The measuring device as claimed in claim 11, wherein:
said first microcontroller adapts at least one characteristic of said at least one signal to a current operating state of the measuring device and/or sets the characteristic in such a manner that the efficiency of energy transmission is optimized.

13. The measuring device as claimed in claim 11, wherein:
the characteristic of said at least one signal set by said first microcontroller is the frequency of said at least one signal and/or the pulse duration to pause duration ratio.

14. The measuring device as claimed in claim 11, wherein:
said transmission unit includes at least one transformer.

15. The measuring device as claimed in claim 14, wherein:
said transmission unit is a push pull converter.

16. The measuring device as claimed in claim 11, wherein:
said first microcontroller registers a present input power of said transmission unit;
said second microcontroller registers a current output power of said transmission unit; and
said first microcontroller and/or said second microcontroller ascertains from the registered input power and the registered output power the present efficiency of the energy transmission.

17. The measuring device as claimed in claims 14, wherein:
said first microcontroller and/or said second microcontroller determines from the ascertained efficiency whether a coil break is present in said at least one transformer and produces in the case of a coil break a corresponding defect report.

18. The measuring device as claimed in claim 11, wherein:
said first microcontroller has different operating modes, which are characterized by certain values of at least one characteristic of said at least one signal;
an operating mode is associated with each operating state of the measuring device; and
said first microcontroller sets the operating mode as a function of the current operating state.

19. The measuring device as claimed in claim 11, wherein:
said first microcontroller registers an identification of said sensor unit, and sets, as a function of said sensor unit present, the at least one characteristic of said at least one signal in such a manner that the energy transmission is matched to the energy requirement of said respective sensor unit.

20. The method for operating a measuring device for determining and/or monitoring at least one process variable, which comprises at least one sensor unit having at least one sensor sensitive for the process variable, a first electronics unit, which is associated with an energy supply unit and which has a first microcontroller, and a second electronics unit, which is associated with the sensor unit and has a second microcontroller, and which is connected with the first electronics unit via a galvanically isolated transmission unit for energy- and data transmission, comprising the steps of:
producing at least one signal having at least one variable characteristic;
feeding said at least one signal to the transmission unit; and
determining at least one current operating parameter by controlling energy- and data transmission by the signal, and at least one characteristic of the signal is set as a function of the operating parameter.
